(19) United States
(12) Patent Application Publication
(10) Pub. No.: US 2021/0129422 A1
(43) Pub. Date: May 6, 2021

(54) ADDITIVE PROCESSES FOR MODIFYING A SURFACE OF AN ARTICLE

(71) Applicant: Polymer Solutions International Inc., Medford, NJ (US)

(72) Inventor: John A. Spadavecchia, Medford, NJ (US)

(73) Assignee: Polymer Solutions International Inc., Medford, NJ (US)

(21) Appl. No.: 17/083,639

(22) Filed: Oct. 29, 2020

Related U.S. Application Data
(60) Provisional application No. 62/928,617, filed on Oct. 31, 2019.
(60) Provisional application No. 63/031,252, filed on May 28, 2020.

(51) Int. Cl. B29C 64/118; B33Y 10/00; B29C 64/209; B29C 64/232

(52) U.S. Cl. CPC B29C 64/118; B33Y 10/00; B33Y 30/00; B29C 64/232; B29C 64/209

(57) ABSTRACT

Processes for modifying a surface geometry of a thermoplastic part are provided. One process includes placing a thermoplastic part in proximity to a head of an extruder; positioning the extruder head relative to a surface of the thermoplastic part; extruding plasticized material from the extruder head to the surface of the thermoplastic part such that the plasticized material exerts a first melt pressure on both of the extruder head and the thermoplastic part; moving the extruder head from a first position to a second position corresponding on the surface; producing a portion of plasticized material having a thickness that is substantially constant between the first position and the second position; and cooling the plasticized material to fuse it to the surface. The head may be movable on guide rails, and the surface and head may be urged to a predetermined position relative to each other by one or more springs.

### FIELD

The present disclosure relates generally to additive processes for modifying the surface geometry of a previously manufactured article.

### BACKGROUND

Injection molding is a commonly used process to produce thermoplastic articles used in a wide variety of applications. Molds used in injection molding must be built according to desired specifications in order to provide the desired part geometry.

Some injection molded products require features that are not feasible to produce in an injection mold. Other injection molded products require complex designs that can make the cost of the tooling cost prohibitive, particularly for larger parts. Product designs are often made more complicated when special surface features are required. For example, some thermoplastic products require the addition of an anti-slip surface to prevent items from sliding or slipping on the surface of the product. Other thermoplastic products require the addition of a shock absorbing cushion and/or scratch-resistant covering to reduce damage to the product and/or to items that come in contact with the product.

Other injected molded products can require customized changes or refinements that are requested by a customer or end user based on a specific need. These changes or refinements can require the attachment of material to change the geometry of the finished thermoplastic product.

There are many known methods for changing the surface geometry of a thermoplastic article. These methods have many drawbacks, particularly methods that bond materials to surfaces of thermoplastic articles. Many methods result in a relatively weak bond that can break down over time. Other methods are incapable of attaching materials to the thermoplastic part at precise locations or in specific arrangements, particularly in applications where high production speed is required. Methods that are capable of attaching materials with precision and speed can often be too costly where limited production volumes dictate a lower cost application method.

Relatedly, the addition of materials to the surface of pre-fabricated articles (whether comprised of thermoplastic, metal, ceramic, or other materials) raises still further challenges. The surface of the article may not be entirely flat and may include numerous variations and imperfections in the z-axis direction. To the extent the addition of material relies on automatic processes (e.g., 3D printing), these surface variations can result in the uneven extrusion of material during the automated process. These surface variations can be accounted for by digital mapping of the surface of the pre-fabricated article (and, e.g., editing of the g-code for the printer), but this process is costly and time-consuming.

The foregoing description is provided as a preface for the following description, and should not be interpreted as an admission that any of the foregoing information constitutes prior art. One or more of the foregoing drawbacks may be mitigated or addressed by apparatuses and processes described in the next sections.

### SUMMARY

In one aspect of the present disclosure, a process for modifying the surface geometry of a thermoplastic part includes the following steps:
A. placing a thermoplastic part (cooled or heated) in proximity to a pellet extruder, the pellet extruder and extruder head;
B. loading pellets comprising thermoplastic material into the pellet extruder;
C. heating the pellets in the pellet extruder until at least some of the pellets become plasticized material;
D. moving the extruder head relative to the thermoplastic part so that the extruder head faces a predetermined target point on a surface of the thermoplastic part;
E. advancing a portion of the plasticized material out of the extruder head and directly onto the surface of the thermoplastic part at the predetermined target point; and
F. cooling said portion of the plasticized material to permanently fuse it to the surface of the thermoplastic part at the predetermined target point.

In another aspect of the present disclosure, the plasticized material can form a functional surface on the surface of the thermoplastic part.

In another aspect of the present disclosure, the functional surface can be or include an anti-slip surface, a scratch resistant surface and/or a shock absorbing surface.

In another aspect of the present disclosure, the plasticized material can form an ornamental surface on the surface of the thermoplastic part.

In another aspect of the present disclosure, the plasticized material can form indicia on the surface of the thermoplastic part.

In another aspect of the present disclosure, the plasticized material can form a raised projection on the surface of the thermoplastic part.

In another aspect of the present disclosure, the plasticized material can fill a void in the surface of the thermoplastic part.

In another aspect of the present disclosure, the plasticized material can be flush with a portion of the surface of the thermoplastic part that is adjacent the void.

In another aspect of the present disclosure, steps D, E and F above can be repeated at a plurality of target points on the surface of the thermoplastic part.

In another aspect of the present disclosure, the plasticized material can form a plurality of raised surfaces on the surface of the thermoplastic part at a plurality of target points.

In another aspect of the present disclosure, the plurality of raised surfaces can be arranged as a plurality of concentric circles.

In another aspect of the present disclosure, the plurality of raised surfaces can be arranged as a plurality of concentric polygons.

In another aspect of the present disclosure, the plurality of raised surfaces can be arranged in a uniform pattern on the surface of the thermoplastic part.

In another aspect of the present disclosure, the pellets can be formed of a thermoplastic elastomer (TPE), a thermoplastic vulcanizate (TPV), styrene-ethylene-butylene-styrene (SEBS), or linear low-density polyethylene (LLDPE).

In another aspect of the present disclosure, the pellets can be formed of the same material as the thermoplastic part.

In another aspect of the present disclosure, the thermoplastic part can be a thermoplastic pallet, slip sheet, top frame, tote or dolly.

In another aspect of the present disclosure, the pellet extruder is part of a CNC machine having a controller.

In another aspect of the present disclosure, a controller controls movement of the extruder head.

In another aspect of the present disclosure, the process includes the step of programming a controller to move the extruder head to one or more positions relative to a thermoplastic part.

In another aspect of the present disclosure, the plasticized material can be advanced out of the extruder at an extrusion rate, and the controller can control the extrusion rate.

In another aspect of the present disclosure, a controller can modulate the extrusion rate based on a velocity of movement of the extruder head to optimize fusion between the plasticized material and the thermoplastic part.

In another aspect of the present disclosure, the process includes the step of changing the position of the extruder head while the thermoplastic part is stationary.

In another aspect of the present disclosure, the process includes the step of changing the position of the thermoplastic part while the extruder head is stationary.

In another aspect of the present disclosure, the process includes the step of changing the position of the extruder head while the thermoplastic part is moving.

In another aspect of the present disclosure, the process includes the step of changing the position of the thermoplastic part while the extruder head is moving.

In another aspect of the present disclosure, the pellet extruder is part of a large format 3D printer.

In another aspect of the present disclosure, the 3D printer is a Cartesian printer.

In another aspect of the present disclosure, the pellet extruder is carried by a 5-axis robotic arm.

In another aspect of the present disclosure, a process for modifying the surface geometry of a thermoplastic part includes the following steps:
A. placing a thermoplastic part having x, y, and z axes in proximity to an extruder, the extruder having an extruder head configured to extrude plasticized material therefrom;
B. positioning the extruder head relative to a surface of the thermoplastic part;
C. extruding the plasticized material from the extruder head to the surface of the thermoplastic part such that the plasticized material exerts a first melt pressure on both of the extruder head and the thermoplastic part;
D. moving the extruder head from a first position corresponding to first target point on the surface of the thermoplastic part to a second position corresponding to a second target point on the surface of the thermoplastic part;
E. producing a first portion of plasticized material having a thickness T that is substantially constant between the first target point and the second target point; and
F. cooling said first portion of the plasticized material to fuse it to the surface of the thermoplastic part at the predetermined target point.

In another aspect of the present disclosure, the surface of the thermoplastic part includes one or more z-axis variations having surface variations in the z-axis direction between the first target point and the second target point.

In another aspect of the present disclosure, the extruder head is in communication with a spring configured to urge the extruder head towards the surface of the thermoplastic part, and the extruder head is configured to move from a first z coordinate to a second z coordinate to compensate for the one or more z-axis variations.

In another aspect of the present disclosure, the thermoplastic part is in communication with a spring configured to urge the surface of the thermoplastic part towards the extruder head, and the surface of the thermoplastic part is configured to move from a first z coordinate (xa, yb, z1) to a second z coordinate (xa, yb, z2) to compensate for the one or more z-axis variations.

In another aspect of the present disclosure, upon the extruder encountering the one or more z-axis variations, the plasticized material exerts a second melt pressure between the extruder head and the thermoplastic part.

In another aspect of the present disclosure, in response to the second melt pressure, the spring expands or contracts to maintain a substantially constant distance between the extruder head and the surface of the thermoplastic part.

In another aspect of the present disclosure, the spring urges a substantially constant distance between the extruder head and the surface of the thermoplastic part.

In another aspect of the present disclosure, the spring is configured to be displaced by a range of melt pressures associated with the plasticized material.

In another aspect of the present disclosure, the process further includes the step of adjusting the z-axis location of the extruder head at the one or more z-axis variations in response to a second melt pressure exerted by the plasticized material on both of the extruder head and the thermoplastic part.

In another aspect of the present disclosure, the second melt pressure is greater than the first melt pressure and wherein the second melt pressure contracts the spring relative to the first melt pressure.

In another aspect of the present disclosure, the second melt pressure is less than the first melt pressure and wherein the second melt pressure expands the spring relative to the first melt pressure.

In another aspect of the present disclosure, the extruder further includes one or more vertical guide rails upon which the extruder head may travel from the first z coordinate to the second z coordinate.

In another aspect of the present disclosure, a process for modifying the surface geometry of a thermoplastic part includes the following steps:
A. placing a thermoplastic part having x, y, and z axes in proximity to an extruder in communication with a spring, the extruder having an extruder head mounted on one or more z-axis guide rails, the extruder head configured to extrude plasticized material therefrom;
B. positioning the extruder head relative to a surface of the thermoplastic part;

C. extruding the plasticized material from the extruder head to the surface of the thermoplastic part such that the plasticized material exerts a first melt pressure on both of the extruder head and the thermoplastic part;
D. moving the extruder head from a first position corresponding to first target point on the surface of the thermoplastic part to a second position corresponding to a second target point on the surface of the thermoplastic part, the thermoplastic part including one or more z-axis variations comprising surface variations in the z-axis direction between the first target point and the second target point;
E. urging the extruder head along the z-axis guide rails from a first z coordinate (xₐ, y_{b}, z₁) to a second z coordinate (xₐ, y_{b}, z₂) upon encountering the one or more z-axis variations;
F. producing a first portion of plasticized material having a thickness T that is substantially constant between the first target point and the second target point; and
G. cooling said first portion of the plasticized material to fuse it to the surface of the thermoplastic part at the predetermined target point.

In another aspect of the present disclosure, the spring urges the extruder head towards the surface of the thermoplastic part.

In another aspect of the present disclosure, the urging step further includes urging the extruder head along the z-axis guide rails from a first z coordinate (xₐ, y_{b}, z₁) to a second z coordinate (xₐ, y_{b}, z₂) upon encountering a first of the one or more z-axis variations and in response to a second melt pressure exerted by the plasticized material on both of the extruder head and the thermoplastic part.

In another aspect of the present disclosure, the second melt pressure is greater than the first melt pressure and the second melt pressure contracts the spring relative to the first melt pressure.

In another aspect of the present disclosure, the second melt pressure is less than the first melt pressure and the second melt pressure expands the spring relative to the first melt pressure.

In another aspect of the present disclosure, the urging step further includes urging the extruder head along the z-axis guide rails from the second z coordinate (xₐ, y_{b}, z₂) to a third z coordinate (xₐ, y_{b}, z₃) upon encountering a second of the one or more z-axis variations and in response to a third melt pressure exerted by the plasticized material on both of the extruder head and the thermoplastic part.

In another aspect of the present disclosure, the steps D, E, F, and G above are repeated at a plurality of target points on the surface of the thermoplastic part.

In another aspect of the present disclosure, a process for modifying the surface geometry of a substrate includes the following steps:
A. placing the substrate in proximity to an extruder in communication with a spring, the extruder having an extruder head mounted on one or more z-axis guide rails, the extruder head configured to extrude material therefrom;
B. positioning the extruder head relative to a surface of the substrate;
C. extruding the material from the extruder head to the surface of the thermoplastic part such that the extruded material exerts a first melt pressure on both of the extruder head and the substrate;
D. moving the extruder head from a first position corresponding to first target point on the surface of the substrate to a second position corresponding to a second target point on the surface of the substrate, the substrate including one or more z-axis variations having surface variations in the z-axis direction between the first target point and the second target point;
E. urging the extruder head along the z-axis guide rails from a first z coordinate (xₐ, y_{b}, z₁) to a second z coordinate (xₐ, y_{b}, z₂) upon encountering the one or more z-axis variations; and
F. producing a first portion of extruded material having a thickness T that is substantially constant between the first target point and the second target point.

In another aspect of the present disclosure, the substrate is one or more of a polymeric substrate, a thermoplastic substrate, a metallic substrate, a ceramic substrate, a stone substrate, and a wooden substrate.

In another aspect of the present disclosure, the extruded material is selected from the group consisting of filament, pellets, resin, powder, and wire.

In another aspect of the present disclosure, the extruded material is one or more of a plasticized material, a metal material, a ceramic material, and a conductive material.

In another aspect of the present disclosure, the urging step further includes urging the extruder head along the z-axis guide rails from a first z coordinate (xₐ, y_{b}, z₁) to a second z coordinate (xₐ, y_{b}, z₂) upon encountering a first of the one or more z-axis variations and in response to a second melt pressure exerted by the extruded material on both of the extruder head and the substrate.

In another aspect of the present disclosure, the second melt pressure is greater than the first melt pressure and wherein the second melt pressure contracts the spring relative to the first melt pressure.

In another aspect of the present disclosure, the second melt pressure is less than the first melt pressure and wherein the second melt pressure expands the spring relative to the first melt pressure.

In another aspect of the present disclosure, the urging step further comprises urging the extruder head along the z-axis guide rails from the second z coordinate (xₐ, y_{b}, z₂) to a third z coordinate (xₐ, y_{b}, z₃) upon encountering a second of the one or more z-axis variations and in response to a third melt pressure exerted by the extruded material on both of the extruder head and the substrate.

In another aspect of the present disclosure, steps D, E, and F are repeated at a plurality of target points on the surface of the substrate.

### BRIEF DESCRIPTION OF THE DRAWING FIGURES

The following detailed description section will be better understood in conjunction with non-limiting examples shown in the drawing figures, of which:

FIG. 1 is a schematic perspective view of an apparatus applying a modified surface to a thermoplastic article according to the present disclosure, with the modified surface formed in a first configuration;

FIG. 1A is a magnified schematic view in partial cross section of a nozzle tip of the apparatus in FIG. 1, shown while modifying the surface of the thermoplastic article;

FIG. 2 is a perspective view of a thermoplastic article having a modified surface formed in a second configuration according to the present disclosure;

FIG. 3 is a perspective view of a thermoplastic article having a modified surface formed in a third configuration according to the present disclosure;

FIG. 4 is a perspective view of a thermoplastic article having a modified surface formed in a fourth configuration according to the present disclosure;

FIG. 5A is a perspective view of a thermoplastic article having a modified surface formed in a fifth configuration according to the present disclosure, with the thermoplastic article supporting a plurality of crates;

FIG. 5B is an exploded perspective view of the thermoplastic article and crates in FIG. 5A, with the modified surface visible on a surface of the thermoplastic article.

FIG. 6 is a schematic perspective view of another apparatus after it has applied a modified surface to a thermoplastic article according to the present disclosure, with the modified surface formed in the same configuration shown in FIG. 1;

FIG. 7 is a flow diagram of a process for creating a modified surface on a thermoplastic article according to a first example;

FIG. 8 is a flow diagram of a process for creating a modified surface on a thermoplastic article according to a second example;

FIG. 9 is a schematic perspective view of an apparatus applying a modified surface to a substrate according to the present disclosure, with the modified surface formed in a first configuration;

FIG. 9A is a magnified schematic view in partial cross section of a nozzle tip of the apparatus in FIG. 9;

FIG. 9B is a magnified schematic view in partial cross section of an alternative arrangement of the apparatus in FIG. 9;

FIG. 10 is a schematic perspective view of an apparatus applying a modified surface to a substrate according to the present disclosure, with the modified surface formed in a first configuration;

FIG. 10A is a magnified schematic view in partial cross section of a nozzle tip of the apparatus in FIG. 10 while modifying the surface of the substrate approaching a surface variation in the surface of the substrate;

FIG. 10B is a magnified schematic view in partial cross section of a nozzle tip of the apparatus in FIG. 10 while modifying the surface of the substrate at a surface variation in the surface of the substrate;

FIG. 10C is a magnified schematic view in partial cross section of a nozzle tip of the apparatus in FIG. 10 while modifying the surface of the substrate approaching a surface variation in the surface of the substrate;

FIG. 10D is a magnified schematic view in partial cross section of a nozzle tip of the apparatus in FIG. 10 while modifying the surface of the substrate at and following a surface variation in the surface of the substrate;

FIG. 10E is a magnified schematic view in partial cross section of a nozzle tip of the apparatus in FIG. 10 while modifying the surface of the substrate approaching a surface variation in the surface of the substrate; and

FIG. 10F is a magnified schematic view in partial cross section of a nozzle tip of the apparatus in FIG. 10 while modifying the surface of the substrate at and following a surface variation in the surface of the substrate.

### DESCRIPTION

Challenges with thermoplastic articles described in the Background section may be addressed in many respects by processes and apparatuses described herein.

The processes and apparatuses described herein are described using terminology defined as set forth below.

The term “thermoplastic part”, as used herein, refers to a product, apparatus, component or other article of manufacture that has at least one surface made of thermoplastic material.

The term “substrate,” as used herein, and as further described below, includes any product, apparatus, component or other article of manufacture. A “thermoplastic part” is one type of substrate. Substrates are, however, not limited to thermoplastic parts and may be made from materials other than thermoplastic.

The phrases “modified surface”, “modifying surface” and the like, as used herein, refer to a surface of a previously manufactured thermoplastic part that is changed, or the act of changing the geometry of a surface of a previously manufactured thermoplastic part. For example, the phrase can refer to adding material onto the surface of the previously injected molded part. The added material can be formed of a thermoplastic elastomer, and can define one or more raised surfaces on the surface of the thermoplastic part. Alternatively, the added material can be added into a void to become flush with the surrounding surface of the thermoplastic part and/or recessed beneath the surrounding surface of the thermoplastic part. The phrases are to be distinguished from objects that are built from scratch by laying down successive layers of material one on top of another, or processes that build objects from scratch by laying down successive layers of material, one on top of another, until the object is created.

Material added to a substrate can form various types of enhancements on the surface of the substrate. Enhancements can include but are not limited to “functional surfaces”, “ornamental surfaces”, and “indicia”.

The term “functional surface”, as used herein, refers to a surface having one or more properties that provide or enhance a utilitarian purpose or benefit. Examples of functional surfaces include, but are not limited to, anti-slip surfaces, shock absorbing surfaces and scratch-resistant surfaces on the surface of a thermoplastic part. “Anti-slip surfaces” can be formed by adding material that exhibits a coefficient of friction after cooling that is higher than the coefficient of friction on the surface of the substrate, or by forming a physical impediment to sliding movement along the surface of the substrate.

The term “ornamental surface”, as used herein, refers to a surface, finish, design element, or other surface characteristic that is applied to or on the substrate to achieve a desired aesthetic appearance or effect.

The term “spring”, as used herein, refers to any device that applies a force over distance (e.g., mechanical spring such as a coil spring or leaf spring, a resilient member comprising a compressible solid such as an elastomeric block, a pneumatic or hydraulic piston and cylinder arrangement having a compressible gas reservoir or accumulator configured to bias the piston outwards from the cylinder, etc.).

The term “indicia”, as used herein, refers to letters, numbers, symbols, logos, trademarks, tradenames, rulings, and other markings that convey information.

The term “melt pressure”, as used herein, refers to the lifting force created by the extruded material in contact with the nozzle orifice of the extruder head and the surface of the thermoplastic part. The melt pressure is a function of a number of elements, including the rate of extrusion, the density and viscosity of the extruded material (which may be, e.g., plasticized material, metallic material, ceramic material, etc.), and the area of the nozzle tip which is exposed to the extruded material being deposited on the surface of the substrate.

The term “z-axis,” as used herein, refers to the axis that is perpendicular to the surface of the substrate being modified by the extruder.

Examples of apparatuses and processes for modifying the surface geometry of various substrates will be now be described with reference to the drawing figures.

Apparatuses and processes according to the present disclosure are implemented using conventional or customized computer numerical control (CNC) machines that use data to control and monitor movement and/or activation of machine parts. The following description of CNC machines and controllers applies to the examples that follow, as well as other machine configurations that can be used.

The CNC machine has a controller that works with a number of motors and drive components in the machine. The motors and drive components control movement of a carrier unit that moves the extruder relative to an article. In addition, the motors and drive units control operation of the extruder. The controller operates each motor to execute programmed motions and functions. One or more sensors send feedback to the controller to monitor the position or condition of the drive units and extruder.

The extruder can be any conventional extruder that extrudes material. For example, the extruder can have a rotating helical screw or a reciprocating plunger.

While the following examples are given using a thermoplastic part as a substrate, the invention is not so limited. A person of ordinary skill in the art would understand that other substrates would be compatible with the invention as described herein, including metallic, polymeric, or ceramic substrates, as well as various construction material-based substrates (such as stone, cement, and wood). In general, the methods and systems of the present invention may be used with any substrates having surface imperfections or discontinuities (e.g., surface variations in the z-axis direction). However, it will also be understood that substrates lacking such surface variations may also be used in keeping with the present disclosure.

Similarly, certain examples in this disclosure describe the extruded material as plasticized material. A person of ordinary skill in the art will understand from this disclosure, however, that other extruded materials are within the scope of this invention. The extruded materials compatible with the invention as disclosed herein include all materials which made be made molten and extruded through an extruder including, e.g., plastic materials, plasticized materials, metallic materials, ceramic materials conductive materials, and construction materials (e.g., concrete, cement, mortar, adhesives, etc.). The feedstock for these materials may be supplied to the extruder in any suitable form, such as, for example, pellet, filament, resin, powder, and wire form.

A person of ordinary skill in the art will understand that the substrate and the extruded material should be selected so as have some degree of compatibility such that the extruded material can, following extrusion, be fused and/or adhered to the surface of the substrate. In an exemplary embodiment, the substrate is a thermoplastic part and the extruded material is a plasticized material. In another embodiment, the substrate may be a circuit board, and the extruded material a conductive substance. In yet another embodiment, the substrate is a metallic part and the extruded material is a metallic wire feedstock. It will also be understood that, to the extent the substrate and the extruded material are not, per se, compatible, an intermediary layer having compatible properties (with respect to the extruded material) could be adhered or otherwise affixed to the substrate prior to extruding material onto the intermediary layer.

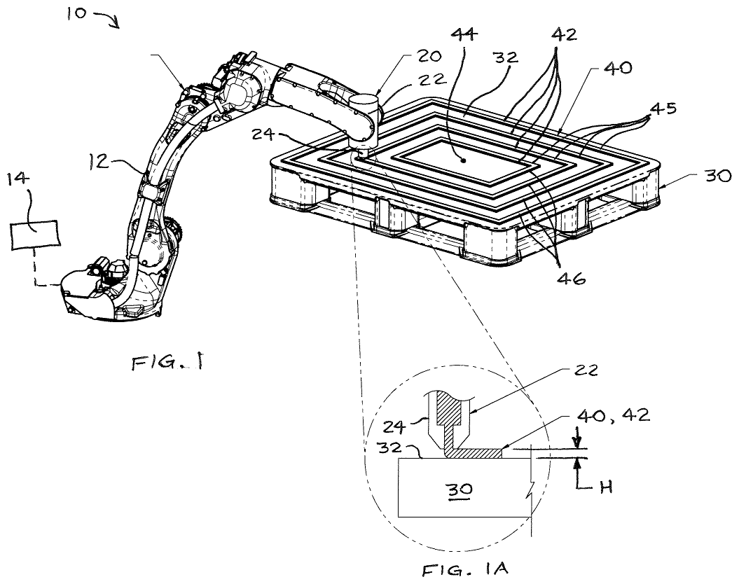

Referring to FIG. 1, an apparatus 10 for modifying the surface of a thermoplastic article is shown according to a first example.

Apparatus 10 is a CNC machine that includes a 5-axis robotic arm 12 and extruder 20. Extruder 20 includes an extruder head 22 having a nozzle tip 24. Robotic arm 12 is operable to position nozzle tip 24 adjacent to a thermoplastic part. Depending on how the robotic arm 12 and thermoplastic part are arranged relative to one another, the robotic arm can position the extruder above the thermoplastic part, beneath the thermoplastic part, or at any other position relative to the thermoplastic part.

In the example in FIG. 1, robotic arm 12 supports and moves nozzle tip 24 above a thermoplastic pallet 30. Thermoplastic pallet 30 has a generally flat thermoplastic surface 32. Apparatus 10 includes a controller 14 for controlling movement of robotic arm 12. Controller 14 is configured to control operation of motors that move robotic arm 12 relative to pallet 30. Controller 14 is also configured to activate and deactivate extruder 20. Moreover, controller 14 is configured to receive feedback from sensors that continuously monitor the position and condition of the drive units and extruder 20. In this arrangement, controller 14 controls movement of robotic arm 12 to position extruder head 22 and nozzle tip 24 at precise locations above pallet 30. The extruder head 22 is moved relative to pallet 30 until nozzle tip 24 aligns with a target point on surface 32. Once nozzle tip 24 is positioned over a target point on surface 32, controller activates extruder 20 to extrude plasticized material onto surface 32 at the target point. After the plasticized material is extruded onto the target point, controller 14 deactivates extruder 20.

Controller 14 is operable to move extruder 20 and nozzle tip 24 to one or more target points on surface 32. In the case of multiple target points, controller 14 moves nozzle tip 24 according to a pattern or shape defined by the target points. As nozzle tip 24 moves through the pattern, plasticized material from extruder 20 is added to surface 32 to create a modified surface 40. Modified surface 40 can be comprised of one or more raised surfaces on surface 32. The height of a raised surface can be uniform over its length, or vary over its length. In addition, or in the alternative, modified surface 40 can be formed by plasticized material extruded into voids that result in one or more surfaces that are flush with surface 32, and/or recessed beneath the surface.

In the current example, modified surface 40 is comprised of a plurality of raised surfaces 42. FIG. 1A shows a magnified view of nozzle tip 24 applying a raised surface 42 on surface 32 of pallet 30. Raised surfaces 42 project upwardly above surface 32 of pallet 30, and have a uniform height H above the pallet surface.

Modified surface elements according to the present disclosure can have various shapes and profiles, including but not limited to line segments, arcs, circles, ovals, regular polygons and irregular polygons. Surface elements can be formed in various arrangements, including arrangements with one or more rows, or arrangements in which elements have a concentric or non-concentric relationship. Moreover, surface elements can be applied in a single layer on the surface of the article, so that the modified surface consists of only one layer of material added to the article.

In FIG. 1, each raised surface 42 defines a hollow rectangle. In addition, each raised surface 42 shares a center point 44 with the other raised surfaces. In this arrangement, the raised surfaces 42 constitute a plurality of concentric regular polygons. The plasticized material that forms the raised surfaces 42 immediately fuses with the thermoplastic material on surface 32, forming a permanent molecular bond between the raised surfaces and the surface of pallet 30. In some applications, the plasticized material can partially melt thermoplastic material on pallet 30, resulting in a modified surface 40 that is partially embedded in surface 32 of pallet 30.

Modified surfaces according to the present disclosure can serve one or more purposes. As noted previously, modified surfaces can form functional surfaces, ornamental surfaces, or indicia on the surface of a thermoplastic article. In the present example, raised surfaces 42 form a functional surface, and more specifically, an anti-slip surface 45 that projects above surface 32 of pallet 30. Anti-slip surface 45 is defined by four rectangular anti-slip elements 46. Each anti-slip element 46 also may comprise a material having higher coefficient of friction than surface 32 under wet or dry conditions. Thus, anti-slip elements 46 are configured to engage and support the bottoms of articles placed on pallet 30 and prevent the articles from slipping and sliding on the pallet 30. Each anti-slip element 46 may also form a physical impediment against sliding movement along the surface of pallet 30 by engaging portions of articles that extend between the plane of the surface 32 and the upper plane of the adjacent anti-slip elements 46.

Modified surfaces according to the present disclosure can be configured in a number of geometric arrangements. Geometric arrangements can be customized according to the dimensions of articles to be placed on the pallet. For example, the shape of each projection, spacing between projections, number of projections, height of projections from the pallet surface, and other variables can be selected according to the shape and/or dimensions of article(s) to be placed on the pallet. These selected parameters can then be inputted in the controller that controls the CNC machine and extruder.

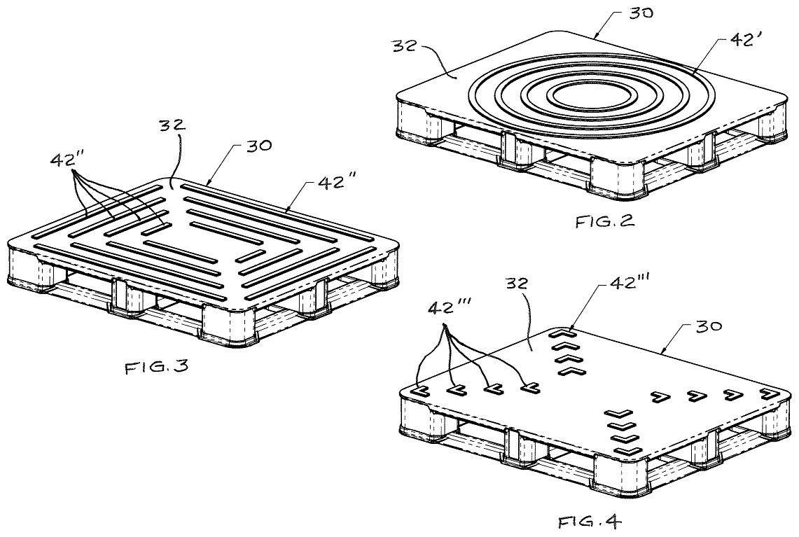

FIG. 2 shows an alternate arrangement in which raised surfaces 42′ are applied as concentric circles on pallet 30. FIG. 3 shows another arrangement in which raised surfaces 42″ are applied as parallel bands or stripes on pallet 30. FIG. 4 shows another arrangement in which raised surfaces 42′″ are applied as carat-shaped or V-shaped elements extending in series from the center of the pallet toward each corner of the pallet. For clarity, only some of the raised surfaces 42′, 42″ and 42′″ or portions thereof are labeled in the Figures.

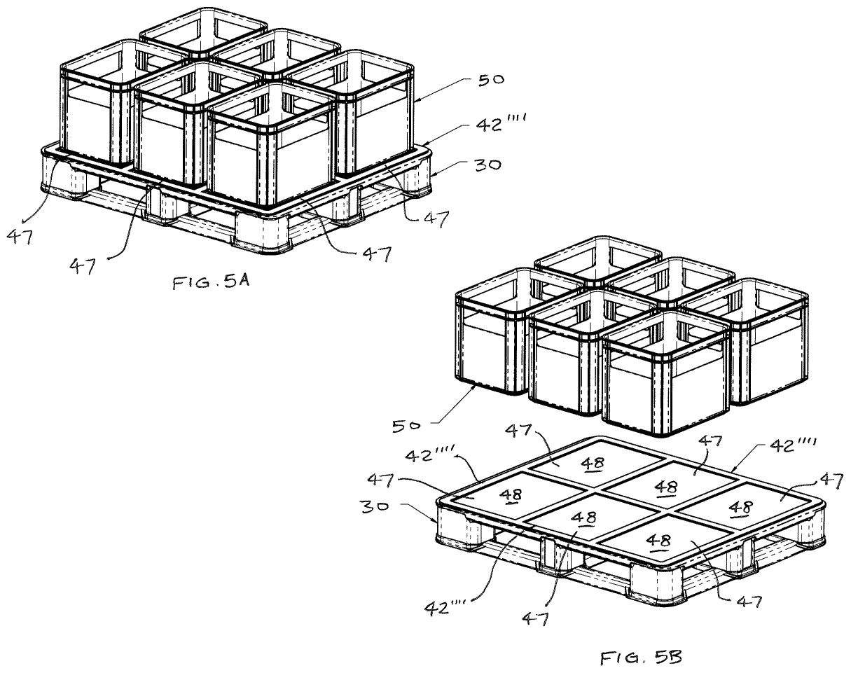

FIGS. 5A and 5B show another arrangement of raised surfaces 42″″ which provide containment perimeters on pallet 30. Raised surfaces 42″″ define six rectangular containment boxes 47. The six containment boxes 47 are configured to securely hold six crates 50 on pallet 30. Each containment box 47 surrounds a receiving area 48 having length and width dimensions that are slightly larger than the length and width of each create 50. In this arrangement, each containment box 47 is configured to receive one crate 50. The raised surfaces 42″″ of each containment box 47 forms walls around all four sides of the crate 50 placed in that containment box. The bottom of each crate 50 is received in one of the containment boxes 47 where it is prevented from sliding or moving on surface 32 by raised surfaces 42″″. For clarity, only some of the raised surfaces 42″″ are labeled in FIGS. 5A and 5B.

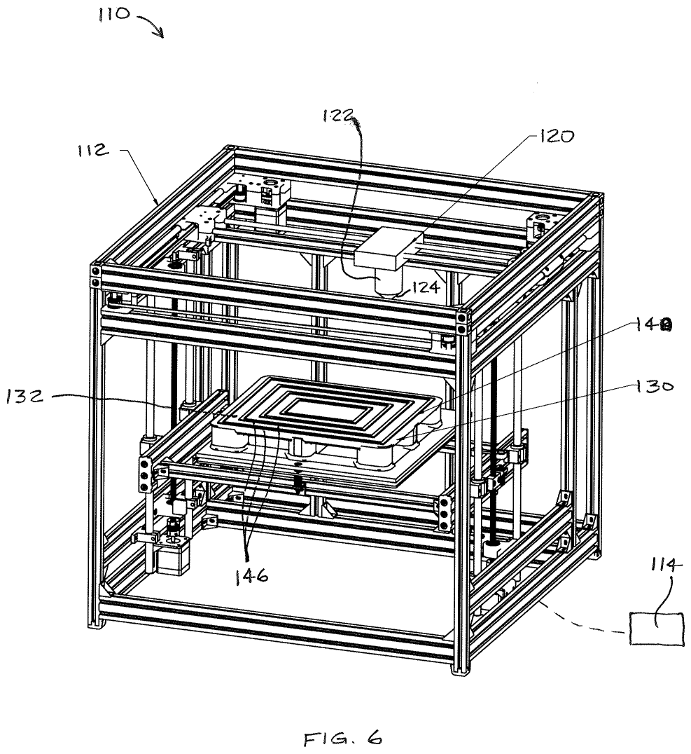

FIG. 6 shows an apparatus 110 for modifying the surface of a thermoplastic article according to a second example. Apparatus 110 is a CNC machine featuring a Cartesian printer 112 and extruder 120. Extruder 120 has an extruder head 122 and nozzle tip 124 that can be positioned and oriented relative to a thermoplastic part. Apparatus 10 also includes a controller 114 for controlling operation of the Cartesian printer 112 and extruder 120. In the current example, apparatus 110 is shown with a thermoplastic pallet 130 after a modified surface 140 is created on a surface 132 of the pallet.

Controller 114 is configured to control operation of motors and receive feedback from sensors to monitor the drive units and extruder 120. As with the previous example, the extruder head 122 is moved relative to pallet 130 until nozzle tip 124 aligns with a target point on surface 132. Once nozzle tip 124 is positioned over a target point on surface 132, controller 114 activates extruder 120 to extrude plasticized material onto surface 132 at the target point. This can be repeated at multiple target points to create a modified surface on pallet 130.

In the case of multiple target points, controller 114 moves nozzle tip 124 according to a pre-programmed pattern or shape. As nozzle tip 124 moves through the pattern, plasticized material from extruder 120 is added to surface 132 to create modified surface 140. Modified surface 140 can be comprised of one or more raised surfaces on surface 132. In addition, or in the alternative, modified surface 140 can be formed by plasticized material extruded into voids that result in one or more surfaces that are flush with surface 132, and/or recessed beneath the surface. In the present example, modified surface 140 is comprised of four raised rectangular anti-slip elements 146, similar to those in FIG. 1. For clarity, only some of the anti-slip elements 146 are labeled in FIG. 6.

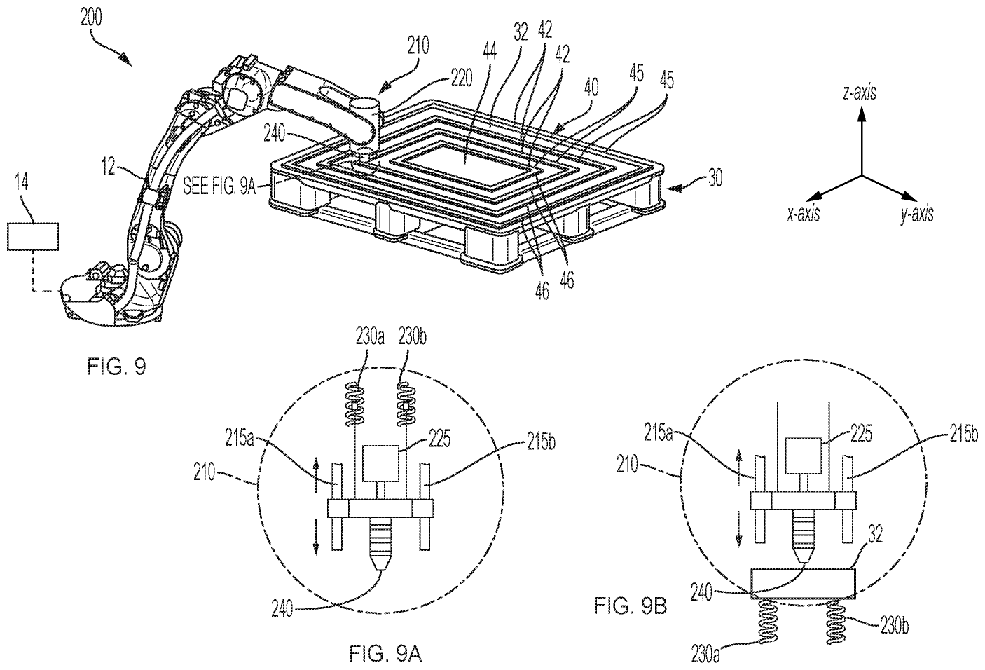

In FIGS. 9 and 9A, an apparatus 200 for modifying the surface of a thermoplastic article is shown according to yet another embodiment.

Apparatus 200 includes a modified extruder 210 having extruder head 220 and including an orifice 240 in communication with one or more springs 230a, b and with one or more vertical guide rails 215a, b.

FIG. 9A depicts an exemplary configuration for extruder 210. Extruder 210 includes a drive motor 225 responsible for extruding (advancing) and retracting plastic feed stock (e.g., pellets, filament, etc.) through an orifice 240. As plasticized material is extruded through orifice 240, a melt pressure is exerted on orifice 240 and thermoplastic pallet 30.

As described above, the magnitude of the melt pressure is based on a number of variables, including the nature of the plasticized material and the area of orifice 240 in contact with the plasticized material as it is extruded onto thermoplastic pallet 30. The melt pressure also depends upon the distance between orifice 240 and thermoplastic pallet 30 during the extrusion process. For example, holding all other aspects constant, the melt pressure will decrease if orifice 240 is moved to a greater distance from thermoplastic pallet 30.

One or more springs 230a, b are configured to urge orifice 240 to maintain a substantially constant distance from the surface of thermoplastic pallet 30 during the extrusion process. For example, one or more springs 230 may be characterized by a mechanical force such that changes in the melt pressure acting on orifice 240 result in displacement (expansion or contraction) of one or more springs. Displacement of one or more springs 230a, b permits orifice 240 to adjust its position normal to the surface of thermoplastic pallet 30 by moving along one or more vertical guide rails 215a, b.

FIG. 9B illustrates an alternative example of how springs 230a, b may be used to urge orifice 240 and surface 32 to a desired predetermined position relative to each other. In this case, springs 230a, b are positioned on the bottom side of pallet 30 to urge pallet 30 upwards towards orifice 240. Springs 230a, b compress and extend depending on the melt pressure exerted between orifice 240 and pallet 30.

It will be appreciated that, in the embodiments of both FIG. 9A and FIG. 9B, one or more springs 230 are used to urge extruder head 220 to a predetermined position relative to surface 32. In the case of FIG. 9A, springs 230a, b may urge the entire extruder head 220 to the desired position, or just a portion of extruder head 230 to the desired position. For example, in FIG. 9A, springs 230a, b urge extruder head 220 to the desired predetermined position relative to surface 32 by biasing orifice 240 away from the remainder of extruder head 220 and towards surface 32. Other alternatives and variations will be apparent to persons of ordinary skill in the art in view of the present disclosure.

Apparatus 200 may be used to modify surfaces which have variations in the z-axis direction, while desirably maintaining consistent adhesion and substantially constant thickness of the deposited plasticized material.

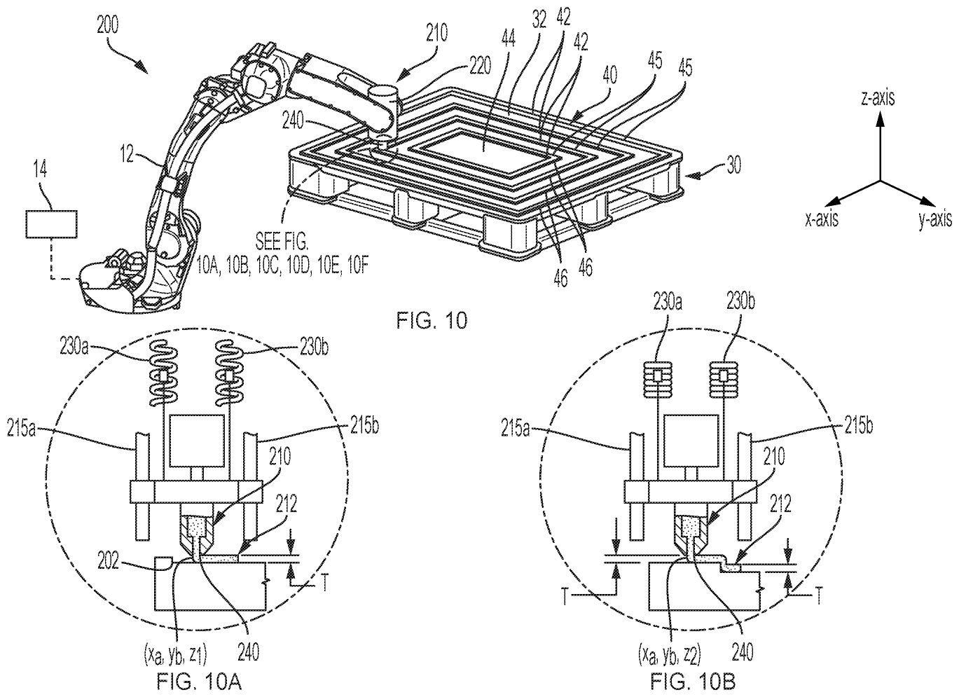

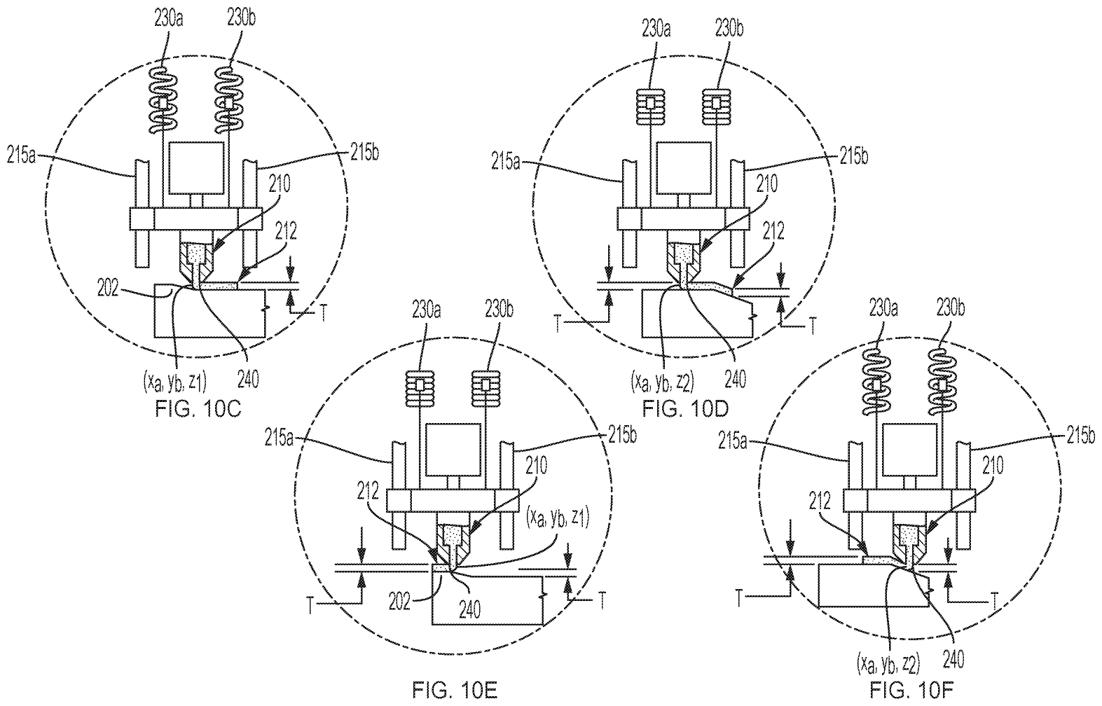

FIGS. 10A and B depict the modification of a substrate having one or more surface variations 202. In FIGS. 10A and B, one or more surface variations is depicted as a “step” in the substrate (e.g., an abrupt change in the z-axis direction).

One or more surface variations 202 are uneven portions of the surface of the substrate. An uneven surface could result in variations in the distance between the nozzle tip 240 and the surface of the substrate, thereby resulting in thickness variations of the deposited extruded material. Such variations can be reduced by repositioning orifice 240 along the z-axis.

FIG. 10A shows the positioning of orifice 240 (xₐ, y_{b}, z₁) is such that continued extrusion at the same z₁ coordinate will affect the thickness T of the first portion of extruded material 212. FIG. 10B depicts a change in the z coordinate positioning of orifice 240 to z₂ (xₐ, y_{b}, z₂). At one or more surface variations 202, the distance between orifice 240 and the surface of the substrate decreases, corresponding to an increase in the melt pressure acting on orifice 240. As shown in FIG. 10B, the increase in melt pressure acting on orifice 240 causes one or more springs 230a, b to compress, thereby lifting orifice 240 along one or more vertical guide rails 215a, b to maintain a constant thickness T.

FIGS. 10C and 10D depict an embodiment in which the one or more surface variations 202 is depicted as a gradual increase in the grade of the substrate (as opposed to the abrupt change depicted in FIGS. 10A and B). FIGS. 10E and F depict an additional type of one or more surface variations 202 in which there is a gradual decrease in the grade of the surface of the substrate. As shown in FIG. 10F, orifice 240 is urged by one or more springs (which expand in response to the lessening of the melt pressure along the decline of the substrate) towards the retreating surface of the substrate, thereby maintaining a constant thickness T of the extruded material.

In yet another embodiment (not shown), one or more springs are in communication with the substrate rather than the extruder. In this embodiment, substantially constant thickness of the extruded material is maintained by changing the position of the substrate rather than the extruder. That is, changes in melt pressure cause corresponding changes in position of the substrate by displacement of the one or more springs. In this embodiment, the one or more springs may be in contact with, e.g., the substrate itself or the build platform upon which the substrate is placed.

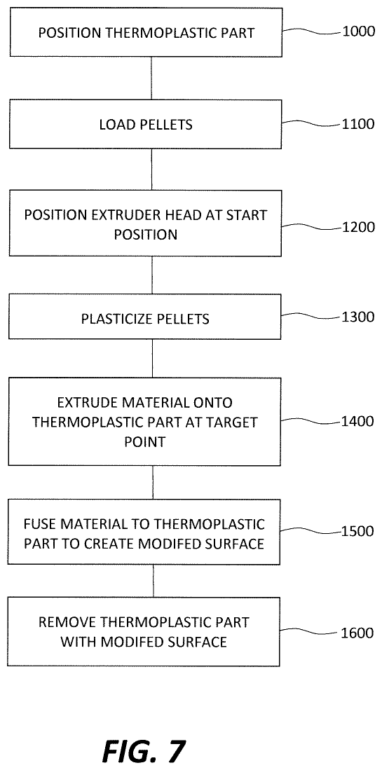

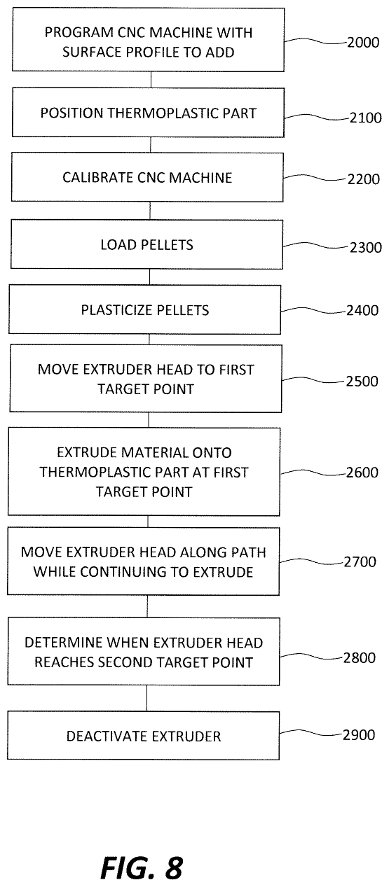

Referring now to FIGS. 7 and 8, two processes for modifying the surface of a thermoplastic article will now be described. Certain steps will be described as being carried out by a controller. It will be understood, however, that one or more of these steps carried out by a controller can also be performed manually by an operator. Therefore, the following examples encompass any and all variations in which one or more steps are performed manually.

Referring to FIG. 7, a process for modifying the surface of a thermoplastic article is summarized according to a first example. In this example, a simplified process for forming a modified surface feature at a single point is described. The process can be completed once the steps are performed. Alternatively, some or all steps can be repeated at multiple points on the surface of the thermoplastic article.

In step 1000, the thermoplastic part is positioned in proximity to a CNC-controlled printing machine. This can be done by placing the thermoplastic part in the machine fixture, or adjacent the machine fixture. The printing machine can be any large format printer, such as apparatus 10 shown in FIG. 1, apparatus 110 shown in FIG. 6, and other machine configurations.

In step 1100, thermoplastic pellets are loaded into the pellet extruder. The pellets can be loaded into a hopper that feeds the pellets into the interior of the extruder by gravity. Pellets can be loaded manually into the hopper. Alternatively, the pellets can be loaded into the hopper by an automated process that continuously adds pellets to keep the hopper filled to capacity. The type of thermoplastic pellet can be selected based on the type material it is being bonded to and the desired properties of the modified surface. For example, thermoplastic pellets containing TPE, TPV, SEBS, LLDPE, or other materials can be selected to create an anti-slip element on the thermoplastic part, the anti-slip element having a coefficient of friction that is higher than that of the surface of the thermoplastic part. Alternatively, thermoplastic pellets containing any compatible thermoplastic can be selected to create a containment perimeter or structure on the surface of the thermoplastic part. Moreover, thermoplastic pellets containing compatible thermoplastic elastomers can be selected to create a shock absorbing or dampening element on the surface of the thermoplastic part. The added material can have a modulus of elasticity and/or other property that makes the material more capable of absorbing shock than the unmodified surface of the thermoplastic part. As described above, the invention is not limited to pellet extruders, and the ordinary skilled artisan will understand that other feedstock (including filament, resin, powder, and wire) can be used depending on the configuration of the extruder (e.g., direct and Bowden-type extruders).

In step 1200, the extruder head is positioned relative to the thermoplastic part at a start position.

In step 1300, the pellets are heated in the pellet extruder until the pellets plasticize. Plasticized material is advanced toward the extruder nozzle by an extrusion screw. The temperature of the heating system and/or rate of advancement are controlled by a controller.

In step 1400, the controller activates the pellet extruder to extrude plasticized material through the nozzle and onto the thermoplastic part at a target point adjacent the start position.

In step 1500, the extrudate fuses with the surface of the thermoplastic part and cools to create the modified surface. Fusion can occur instantaneously or nearly instantaneously as the extrudate contacts the surface of the thermoplastic part in step 1400.

In step 1600, the thermoplastic part with modified surface is removed from the machine.

The process can be halted after the aforementioned steps are completed, resulting in a modified surface at a single target point on the surface of the thermoplastic part. Alternatively, one or more of the aforementioned steps can be repeated or performed simultaneously at other locations to form a modified surface at multiple target points on the surface of the thermoplastic part.

Referring now to FIG. 8, a process for modifying the surface of a thermoplastic article is summarized according to a second example. In step 2000, a controller for a CNC machine is programmed to create a specific surface profile on the surface of a thermoplastic part. As noted above, the CNC machine can be any type of CNC controlled device with pellet extruder.

In step 2100, a thermoplastic part is placed in or adjacent to a CNC controlled printing machine. The CNC controlled printing machine can be any large format printer that includes a pellet extruder, as noted above.

In step 2200, the CNC machine is calibrated so that the position of the extruder head relative to the surface on the thermoplastic article is established. In one possible calibration step, the z-axis is established based on the overall height or thickness of the feature being extruded. As an alternative, the z-axis is continuously modulated based on a closed loop control and sensor. A modulated z-axis can produce more consistent adhesion when parts have surface variations. Alternatively, the z-axis position of one or both of the extruder and the thermoplastic part is modulated automatically in response to differences in melt pressure as described above.

In step 2300, thermoplastic pellets are loaded into the pellet extruder. As noted above, the type of thermoplastic pellet can be selected based on the type of modified surface being produced and the desired properties of the modified surface.

In step 2400, the pellets are heated in the pellet extruder until the pellets plasticize. Plasticized material is advanced toward the extruder nozzle by an extrusion screw or plunger. The temperature of the heating system and/or rate of advancement are controlled by the controller. Plasticizing can occur on a continuous or as needed basis, and as long as plasticized material is needed to complete the modified surface.

In step 2500, the controller moves the extruder head relative to the thermoplastic part until the extruder nozzle is adjacent a first target point on the surface of the thermoplastic part. The first target point can correspond to a “starting” point on the desired surface profile where the modified surface begins.

In step 2600, the controller activates the pellet extruder to extrude plasticized material through the nozzle and onto the thermoplastic part at the first target point. The extrudate fuses with the surface of the thermoplastic part instantaneously or nearly instantaneously and cools.

In step 2700, the controller moves the extruder head relative to the thermoplastic part while continuing to extrude material from the nozzle. The extruder head is moved from the first target point along a path that is programmed into the controller. The path can follow any trajectory that is programmed into the controller, including but not limited to a linear path, curved path, zig zag path, undulating or wave-shaped path, or other path that corresponds to the desired surface profile. Plasticized material fuses with the surface of the thermoplastic part as the extruder head moves along the path.

In step 2800, the controller monitors the position of the extruder head relative to the thermoplastic part and determines when the extruder head reaches a second target point. The second target point can correspond to a finish point or a break point, as described in the previous example.

In step 2900, the controller deactivates the extruder to stop further extrusion of material onto the surface of the thermoplastic part. Where the second target point is a finish point, the modified surface is completed, and the thermoplastic part can be removed from the machine. Where the second target point is a break point, the controller moves the extruder head to another target point on the surface of the thermoplastic part corresponding to a point where extrusion resumes. Upon reaching the point where extrusion resumes, steps 2600-2900 can be repeated until the finish point is reached and the modified surface is complete.

It will be appreciated that processes and apparatuses according to the present disclosure can be used in a variety of applications to produce and modify a variety of substrates. Non-limiting examples of thermoplastic parts produced according to the present disclosure include but are not limited to articles used for product storage and handling, including but not limited to pallets, slip sheets, top frames, totes and dollies. Other examples include but are not limited to pre-fabricated structural components and/or surfaces used in wet environments, including but not limited to boat decks, stairs, ramps, diving podiums, and diving boards. It will be appreciated that the foregoing examples are only a partial list of applications, and that processes and apparatuses according to the present disclosure can be used equally well for other applications and end products.

Apparatuses and processes according to the present disclosure can be operated and carried out by moving an extruder head relative to a stationary substrate. Alternatively, the apparatuses and processes can be operated and carried out by moving an extruder head relative to a moving substrate. Moreover, the apparatuses and processes can be operated and carried out by moving a substrate relative to a stationary extruder head.

Accordingly, the present disclosure encompasses all of the foregoing possibilities. In addition, the present disclosure encompasses apparatuses and processes that include or carry out any combination of features or steps described in the present disclosure, whether presented in the same example or presented in separate examples. It is further intended that the appended claims cover all such variations as fall within the scope of the present disclosure.

What is claimed:

1. A process for modifying a surface geometry of a thermoplastic part, the process comprising:
A. placing a thermoplastic part having x, y, and z axes in proximity to an extruder, the extruder having an extruder head configured to extrude plasticized material therefrom;
B. positioning the extruder head relative to a surface of the thermoplastic part;
C. extruding the plasticized material from the extruder head to the surface of the thermoplastic part such that the plasticized material exerts a first melt pressure on both of the extruder head and the thermoplastic part;
D. moving the extruder head from a first position corresponding to first target point on the surface of the thermoplastic part to a second position corresponding to a second target point on the surface of the thermoplastic part;
E. producing a first portion of plasticized material having a thickness T that is substantially constant between the first target point and the second target point; and
F. cooling said first portion of the plasticized material to fuse it to the surface of the thermoplastic part at the predetermined target point.

2. The process of claim 1, wherein the surface of the thermoplastic part comprises one or more z-axis variations comprising surface variations in the z-axis direction between the first target point and the second target point.

3. The process of claim 2, further comprising urging the extruder head and the surface of the thermoplastic force to a predetermined relative position with a spring.

4. The process of claim 3, wherein the extruder head is in communication with a spring configured to urge the extruder head towards the surface of the thermoplastic part, and wherein the extruder head is configured to move from a first z coordinate to a second z coordinate to compensate for the one or more z-axis variations.

5. The process of claim 3, wherein the thermoplastic part is in communication with a spring configured to urge the surface of the thermoplastic part towards the extruder head, and wherein the surface of the thermoplastic part is configured to move from a first z coordinate (xₐ, y_{b}, z₁) to a second z coordinate (xₐ, y_{b}, z₂) to compensate for the one or more z-axis variations.

6. The process of claim 3, wherein, upon the extruder encountering the one or more z-axis variations, the plasticized material exerts a second melt pressure between the extruder head and the thermoplastic part.

7. The process of claim 6, wherein, in response to the second melt pressure, the spring expands or contracts to maintain a substantially constant distance between the extruder head and the surface of the thermoplastic part.

8. The process of claim 3, wherein the spring urges a substantially constant distance between the extruder head and the surface of the thermoplastic part.

9. The process of claim 3, wherein the spring is configured to be displaced by a range of melt pressures associated with the plasticized material.

10. The process of claim 3, further comprising adjusting the z-axis location of the extruder head at the one or more z-axis variations in response to a second melt pressure exerted by the plasticized material on both of the extruder head and the thermoplastic part.

11. The process of claim 10, wherein the second melt pressure is greater than the first melt pressure and wherein the second melt pressure contracts the spring relative to the first melt pressure.

12. The process of claim 10, wherein the second melt pressure is less than the first melt pressure and wherein the second melt pressure expands the spring relative to the first melt pressure.

13. The process of claim 3, wherein the extruder further comprises one or more vertical guide rails upon which the extruder head may travel from the first z coordinate to the second z coordinate.

14. A process for modifying a surface geometry of a thermoplastic part, the process comprising:
A. placing a thermoplastic part in proximity to an extruder in communication with a spring, the extruder comprising an extruder head mounted on one or more z-axis guide rails, the extruder head configured to extrude plasticized material therefrom;
B. positioning the extruder head relative to a surface of the thermoplastic part;
C. extruding the plasticized material from the extruder head to the surface of the thermoplastic part such that the plasticized material exerts a first melt pressure on both of the extruder head and the thermoplastic part;
D. moving the extruder head from a first position corresponding to first target point on the surface of the thermoplastic part to a second position corresponding to a second target point on the surface of the thermoplastic part, the thermoplastic part including one or more z-axis variations comprising surface variations in the z-axis direction between the first target point and the second target point;
E. urging the extruder head along the z-axis guide rails from a first z coordinate (xₐ, y_{b}, z₁) to a second z coordinate (xₐ, y_{b}, z₂) upon encountering the one or more z-axis variations;
F. producing a first portion of plasticized material having a thickness T that is substantially constant between the first target point and the second target point; and
G. cooling said first portion of the plasticized material to fuse it to the surface of the thermoplastic part at the predetermined target point.

15. The process of claim 14, wherein the spring urges the extruder head towards the surface of the thermoplastic part.

16. The process of claim 14, wherein the urging step further comprises urging the extruder head along the z-axis guide rails from a first z coordinate (xₐ, y_{b}, z₁) to a second z coordinate (xₐ, y_{b}, z₂) upon encountering a first of the one or more z-axis variations and in response to a second melt pressure exerted by the plasticized material on both of the extruder head and the thermoplastic part.

17. The process of claim 16, wherein the second melt pressure is greater than the first melt pressure and wherein the second melt pressure contracts the spring relative to the first melt pressure.

18. The process of claim 16, wherein the second melt pressure is less than the first melt pressure and wherein the second melt pressure expands the spring relative to the first melt pressure.

19. The process of claim 16, wherein the urging step further comprises urging the extruder head along the z-axis guide rails from the second z coordinate (xₐ, y_{b}, z₂) to a third z coordinate (xₐ, y_{b}, z₃) upon encountering a second of the one or more z-axis variations and in response to a third melt pressure exerted by the plasticized material on both of the extruder head and the thermoplastic part.

20. The process of claim 14, wherein steps D, E, F, and G are repeated at a plurality of target points on the surface of the thermoplastic part.

21. A process for modifying a surface geometry of a substrate, the process comprising:
A. placing the substrate in proximity to an extruder in communication with a spring, the extruder comprising an extruder head mounted on one or more z-axis guide rails, the extruder head configured to extrude material therefrom;
B. positioning the extruder head relative to a surface of the substrate;
C. extruding the material from the extruder head to the surface of the thermoplastic part such that the extruded material exerts a first melt pressure on both of the extruder head and the substrate;
D. moving the extruder head from a first position corresponding to first target point on the surface of the substrate to a second position corresponding to a second target point on the surface of the substrate, the substrate including one or more z-axis variations comprising surface variations in the z-axis direction between the first target point and the second target point;
E. urging the extruder head along the z-axis guide rails from a first z coordinate (xₐ, y_{b}, z₁) to a second z coordinate (xₐ, y_{b}, z₂) upon encountering the one or more z-axis variations; and
F. producing a first portion of extruded material having a thickness T that is substantially constant between the first target point and the second target point.

22. The process of claim 21, wherein the substrate is one or more of a polymeric substrate, a thermoplastic substrate, a metallic substrate, a ceramic substrate, a stone substrate, and a wooden substrate.

23. The process of claim 21, wherein the extruded material is selected from the group consisting of pellets, filament, resin, powder, and wire.

24. The process of claim 21, wherein the extruded material is one or more of a plasticized material, a metal material, a ceramic material, and a conductive material.

25. The process of claim 21, wherein the urging step further comprises urging the extruder head along the z-axis guide rails from a first z coordinate (xₐ, y_{b}, z₁) to a second z coordinate (xₐ, y_{b}, z₂) upon encountering a first of the one or more z-axis variations and in response to a second melt pressure exerted by the extruded material on both of the extruder head and the substrate.

26. The process of claim 25, wherein the second melt pressure is greater than the first melt pressure and wherein the second melt pressure contracts the spring relative to the first melt pressure.

27. The process of claim 25, wherein the second melt pressure is less than the first melt pressure and wherein the second melt pressure expands the spring relative to the first melt pressure.

28. The process of claim 25, wherein the urging step further comprises urging the extruder head along the z-axis guide rails from the second z coordinate (xₐ, y_{b}, z₂) to a third z coordinate (xₐ, y_{b}, z₃) upon encountering a second of the one or more z-axis variations and in response to a third melt pressure exerted by the extruded material on both of the extruder head and the substrate.

29. The process of claim 21, wherein steps D, E, and F are repeated at a plurality of target points on the surface of the substrate.
